(19) United States
(12) Patent Application Publication
(10) Pub. No.: US 2016/0251759 A1
(43) Pub. Date: Sep. 1, 2016

(54) ATOMIC LAYER DEPOSITION DEVICE HAVING SCAN-TYPE REACTOR AND METHOD OF DEPOSITING ATOMIC LAYER USING THE SAME

(71) Applicant: KORNIC ENC CO., LTD., Gyeonggi-do (KR)

(72) Inventors: Choon Soo LEE, Gyeonggi-do (KR); Hong Ki JEONG, Gyeonggi-do (KR)

(73) Assignee: KORNIC ENC CO., LTD., Gyeonggi-do (KR)

(21) Appl. No.: 15/022,457

(22) PCT Filed: Sep. 2, 2014
(86) PCT No.: PCT/KR2014/008196

§ 371 Date: Mar. 16, 2016

(30) Foreign Application Priority Data
Sep. 16, 2013 (KR) 10-2013-0111026

(51) Int. Cl. C23C 16/455; H01J 37/32; C23C 16/48; C23C 16/44; C23C 16/50

(52) U.S. Cl. CPC C23C 16/45548; C23C 16/45517; C23C 16/45574; C23C 16/4412; C23C 16/45519; C23C 16/50; C23C 16/45536; C23C 16/48; H01J 37/3244; H01J 37/32834; H01J 37/32899; H01J 2237/332

(57) ABSTRACT

An atomic layer deposition device having a scan-type reactor includes multiple unit process chambers arranged in a stacking type for an atomic layer deposition process. The atomic layer deposition device includes upper and lower process chamber parts able to be separated from and coupled to each other. The scan-type reactor moves between the upper and lower process chamber parts over a substrate to which a raw material precursor is adsorbed, and causes a reaction precursor to react with the raw material precursor.

The device fundamentally eliminates an area of coexistence of the raw material precursor and the reaction precursor, thereby making unnecessary any additional process for removing films so as to prevent films from being deposited outside the substrate, extending the maintenance cycle, and improving thin film quality and productivity through particle generation suppression.

### TECHNICAL FIELD

The present invention relates to a vapor deposition reactor and a film forming method using the same. More particularly, the present invention pertains to an atomic layer deposition device provided with a scan-type reactor and an atomic layer deposition method in which, for the purpose of atomic layer deposition, a plurality of unit process chambers for atomic layer deposition process each provided with an upper and a lower process chamber part which can be separated from and coupled to each other is disposed in a stacked form, and a scan-type reactor for causing a reactant precursor to react with a raw material precursor while moving over a substrate, onto which the raw material precursor is adsorbed, is provided in each of the unit process chambers. This makes it possible to fundamentally eliminate an area of coexistence of the raw material precursor and the reaction precursor, thereby making unnecessary any additional process for removing films which may otherwise be deposited outside the substrate, prolonging a maintenance period, suppressing generation of particles, improving the quality and productivity of films, and providing optimized atomic layer films.

### BACKGROUND ART

In general, as examples of a method of depositing a film of a predetermined thickness on a substrate such as a semiconductor substrate or a glass, there are available a physical vapor deposition (PVD) method such as a sputtering method or the like, which makes use of physical collision, and a chemical vapor deposition (CVD) method which makes use of chemical reaction.

In recent years, as the design rule of a semiconductor device grows extremely fine, a film having a fine pattern is demanded and a step difference in a film formation region is significantly increased. This leads to frequent use of an atomic layer deposition (ALD) method which is capable of uniformly forming a fine pattern of an atomic layer thickness and which is superior in step coverage.

The atomic layer deposition method is similar to a typical chemical vapor deposition method in that the atomic layer deposition method utilizes chemical reaction between gas molecules. However, unlike the typical chemical vapor deposition method in which plural kinds of gas molecules are simultaneously introduced into a process chamber and a reaction product is deposited on a substrate, the atomic layer deposition method is configured to introduce a gas containing one source material into a process chamber and to cause the source material to be adsorbed onto a heated substrate. Thereafter, a gas containing another source material is introduced into the process chamber. Thus, a reaction product generated by chemical reaction between the source materials is deposited on the substrate.

In the meantime, the aforementioned atomic layer deposition method may be used in encapsulating an AMOLED display with a thin film or in forming a barrier film of a flexible substrate, a sunlight buffer layer, a high dielectric constant (high-k) material for semiconductors, a diffusion-preventing film (a TiN film, a TaN film, etc.) of an aluminum (Al) wiring line or a copper (Cu) wiring line, or the like.

The aforementioned atomic layer deposition method performs a process using a single-wafer-type apparatus, a batch-type apparatus or an apparatus having scan-type small reactor configured to move over a substrate, which have heretofore been used in plasma enhanced chemical vapor deposition (PECVD).

In the single-wafer-type apparatus, a process is performed after a single substrate is loaded. The single-wafer-type apparatus includes a moving susceptor for loading, unloading and heating a substrate, a diffuser (mainly, a shower head type diffuser) for supplying a process gas, and an exhaust part. However, in the single-wafer-type apparatus, a process chamber needs to be formed very thick in order to prevent deformation of the process chamber and peripheral portions thereof which may be deformed by the atmospheric pressure during generation of a vacuum.

Furthermore, it is necessary to install a gate valve for dividing a substrate loading/unloading region and a substrate processing region. Thus, when fabricating an apparatus for a large-area substrate, the internal volume of the apparatus is greatly increased. This leads to a problem in that the consumption amount of a raw material precursor and a reactant precursor is sharply increased, the process time is increased due to the increase in the time required for adsorption, purge, reaction and purge, and the productivity is significantly reduced.

Next, the batch-type apparatus is an apparatus which simultaneously processes a plurality of substrates in order to solve the problems of the large volume, the increased consumption of a raw material precursor and a reactant precursor, and the increased maintenance cost and the low productivity inherent in a conventional atomic layer deposition apparatus. The batch-type apparatus has been applied to a solar cell manufacturing process. However, the batch-type apparatus suffers from a problem in that films are simultaneously formed on the top surface of substrate and the back surface thereof, a problem in that the uniformity and reproducibility of films formed on a plurality of substrates is low, and a problem in that a chamber as a whole needs to be separated and cleaned when contaminated.

Next, the apparatus having a scan-type small reactor is an apparatus in which a plurality of small reactors having a length corresponding to the length of one side of a substrate is disposed within a vacuum chamber and in which a film is formed by reciprocating the substrate or the small reactors. The apparatus having a scan-type small reactor has been applied to a display film encapsulating process. However, in the apparatus having a scan-type small reactor, it is difficult to thoroughly control a gas flow on the substrate and the small reactor and to separately supply a raw material precursor and a reactant precursor. This poses a problem in that particles may be generated.

### SUMMARY OF THE INVENTION

### Technical Problems

Accordingly, the present invention provides an atomic layer deposition device provided with a scan-type reactor and an atomic layer deposition method using the same, in which a plurality of unit process chambers for atomic layer deposition process each provided with an upper and a lower process chamber part which can be separated from and coupled to each other is disposed in a stacked form, and a scan-type reactor for causing a reactant precursor to react with a raw material precursor while moving over a substrate, onto which the raw material precursor is adsorbed, is provided in each of the unit process chambers. This makes it possible to fundamentally eliminate an area of coexistence of the raw material precursor and the reaction precursor, thereby making unnecessary any additional process for removing films which may otherwise be deposited outside the substrate, prolonging a maintenance period, suppressing generation of particles, improving the quality and productivity of films, and providing optimized atomic layer films.

### Means for solving the Problems

In accordance with an aspect of the present invention, there is provided an atomic layer deposition device which includes a process chamber, a scan-type reactor and a vacuum chamber. The process chamber includes an upper and a lower process chamber part which are separated from or coupled to each other. The scan-type reactor is configured to wait in a predetermined position outside the process chamber and configured to, when the upper process chamber part and the lower process chamber part are separated from each other, eject a reactant precursor toward a substrate mounted on the upper process chamber part or the lower process chamber part while horizontally moving at a predetermined height above the substrate of the lower process chamber part. The vacuum chamber is configured to support the process chamber and configured to maintain a space, in which the process chamber is positioned, in a vacuum state.

In accordance with another aspect of the present invention, there is provided an atomic layer deposition device which includes a process chamber, a scan-type reactor, and a vacuum chamber. Two or more process chambers each include an upper process chamber part and a lower process chamber part which are separated from or coupled to each other. The scan-type reactors are each configured to wait in a predetermined position outside each of the process chambers and configured to, when the upper process chamber part and the lower process chamber part are separated from each other, eject a reactant precursor toward a substrate mounted on the upper process chamber part or the lower process chamber part while horizontally moving at a predetermined height above the substrate of the lower process chamber part. The vacuum chamber is configured to support the process chambers in a vertically-stacked form and configured to maintain a space, in which the process chambers are stacked, in a vacuum state.

In the atomic layer deposition device, each of the scan-type reactors includes a gas supply portion and a gas exhaust portion. The gas supply portion is formed in a central portion or a side portion of an upper surface or a lower surface of each of the scan-type reactors and configured to eject the reactant precursor. The gas exhaust portion is formed spaced apart from the gas supply portion and configured to exhaust the ejected reactant precursor failing to react with a raw material precursor existing on the substrate, a reaction byproduct or a purge gas.

In the atomic layer deposition device, each of the scan-type reactors further includes a purge gas supply portion formed in opposite side portions or a peripheral portion of the upper surface or the lower surface of each of the scan-type reactors and configured to supply the purge gas.

In the atomic layer deposition device, each of the scan-type reactors is configured to, when the reactant precursor is ejected toward the substrate, cause the purge gas supply portion to eject the purge gas to form a gas barrier between each of the scan-type reactors and the substrate.

In the atomic layer deposition device, the purge gas supply portion is formed in each of the scan-type reactors at an outer side of the gas supply portion and the gas exhaust portion.

In the atomic layer deposition device, each of the scan-type reactors further includes an electrode provided in an upper portion or a lower portion of each of the scan-type reactors and configured to generate plasma.

In the atomic layer deposition device, each of the scan-type reactors is configured to, when the reactant precursor is ejected toward the substrate, supply electric power to the electrode to generate plasma above or below each of the scan-type reactors.

In the atomic layer deposition device, the scan-type reactors are provided in the process chambers in a one-to-one relationship and are driven independently or simultaneously through a connection member which interconnects the scan-type reactors.

In the atomic layer deposition device, the scan-type reactors are moved by a reactor moving unit which moves the connection member.

In the atomic layer deposition device, the reactor moving unit is supported by the vacuum chamber.

In the atomic layer deposition device, the scan-type reactors are supported by the vacuum chamber.

In the atomic layer deposition device, each of the scan-type reactors includes a heat treatment unit or an ultraviolet treatment unit configured to perform cleaning or surface modification with respect to the substrate or a film formed on the substrate.

In accordance with another aspect of the present invention, there is provided an atomic layer deposition device which includes a process chamber, a scan-type reactor and a vacuum chamber. The process chamber includes an upper process chamber part and a lower process chamber part which are separated from or coupled to each other. The scan-type reactor is configured to wait in a predetermined position outside the process chamber and configured to, when the upper process chamber part and the lower process chamber part are separated from each other, cause an inert reactant precursor introduced into the process chamber to react with a raw material precursor on a substrate while horizontally moving at a predetermined height above the substrate of the lower process chamber part. The vacuum chamber is configured to support the process chamber, configured to maintain a space, in which the process chamber is positioned, in a vacuum state, and configured to supply and exhaust the inert reactant precursor.

In accordance with another aspect of the present invention, there is provided an atomic layer deposition device which includes two or more process chambers, scan-type reactors and a vacuum chamber. The two or more process chambers each include an upper process chamber part and a lower process chamber part which are separated from or coupled to each other. The scan-type reactors are each configured to wait in a predetermined position outside each of the process chambers and configured to, when the upper process chamber part and the lower process chamber part are separated from each other, cause an inert reactant precursor introduced into each of the process chambers to react with a raw material precursor on a substrate while horizontally moving at a predetermined height above the substrate of the lower process chamber part. The vacuum chamber is configured to support the process chambers in a vertically-stacked form, configured to maintain a space, in which the process chambers are stacked, in a vacuum state, and configured to supply and exhaust the inert reactant precursor.

In the atomic layer deposition device, each of the scan-type reactors is configured to selectively activate only the inert reactant precursor existing on the substrate by generating plasma above the substrate mounted on the upper process chamber part or the lower process chamber part and is configured to cause the activated inert reactant precursor to react with the raw material precursor.

In the atomic layer deposition device, each of the scan-type reactors is configured to selectively activate only the inert reactant precursor existing on the substrate by irradiating ultraviolet rays or infrared rays toward the substrate mounted on the upper process chamber part or the lower process chamber part and is configured to cause the activated inert reactant precursor to react with the raw material precursor.

In the atomic layer deposition device, each of the scan-type reactors further includes an electrode provided in an upper portion or a lower portion of each of the scan-type reactors and configured to generate plasma.

In the atomic layer deposition device, each of the scan-type reactors is configured to, when each of the scan-type reactors moves toward the substrate, supply electric power to the electrode to generate plasma above or below each of the scan-type reactors.

In the atomic layer deposition device, each of the scan-type reactors includes an ultraviolet irradiation device or an infrared irradiation device installed in an upper portion or a lower portion of each of the scan-type reactors and configured to irradiate the ultraviolet rays or the infrared rays.

In the atomic layer deposition device, each of the scan-type reactors is configured to, when each of the scan-type reactors moves toward the substrate, drive the ultraviolet irradiation device or the infrared irradiation device to irradiate the ultraviolet rays or the infrared rays above or below each of the scan-type reactors.

In the atomic layer deposition device, the inert reactant precursor is a substance which reacts with the raw material precursor when activated by plasma, ultraviolet rays or infrared rays.

In the atomic layer deposition device, the inert reactant precursor is filled into the vacuum chamber under a predetermined pressure.

In the atomic layer deposition device, when the upper process chamber part and the lower process chamber part are separated from each other after the raw material precursor is adsorbed to the substrate, the inert reactant precursor is diffused and introduced from the vacuum chamber into a space between the upper process chamber part and the lower process chamber part separated from each other.

In the atomic layer deposition device, when the upper process chamber part and the lower process chamber part are coupled to each other after the substrate is loaded into each of the process chambers, the inert reactant precursor is filled into the vacuum chamber.

In accordance with another aspect of the present invention, there is provided an atomic layer deposition method performed in an atomic layer deposition device in which a process chamber is positioned within a vacuum chamber. In the method, an upper process chamber part and a lower process chamber part of the process chamber are coupled to form a sealed reaction space, after a substrate and a mask are loaded into the process chamber. Next, a raw material precursor is caused to be adsorbed onto the substrate by performing an atomic layer deposition process within the sealed reaction space. Next, a reactant precursor is ejected toward the substrate using a scan-type reactor, after the raw material precursor is adsorbed onto the substrate. The reactant precursor ejected toward the substrate is caused to react with the raw material precursor.

In accordance with another aspect of the present invention, there is provided an atomic layer deposition method performed in a stacking-type atomic layer deposition device in which two or more process chambers are stacked within a vacuum chamber. In the method, an upper process chamber part and a lower process chamber part of each of the process chambers are coupled to form a sealed reaction space, after a substrate and a mask are loaded into each of the process chambers. Next, a raw material precursor is caused to be adsorbed onto the substrate by performing an atomic layer deposition process within the sealed reaction space. A reactant precursor is ejected toward the substrate using a scan-type reactor, after the raw material precursor is adsorbed onto the substrate. The reactant precursor ejected toward the substrate is caused to react with the raw material precursor.

In the atomic layer deposition method, in ejecting the reactant precursor, the upper process chamber part and the lower process chamber part are separated from each other after the raw material precursor is adsorbed onto the substrate. The reactant precursor is ejected toward the substrate while moving the scan-type reactor in a space between the upper process chamber part and the lower process chamber part.

In the atomic layer deposition method, in ejecting the reactant precursor, the reactant precursor is ejected toward the substrate mounted on the upper process chamber part or the lower process chamber part, while horizontally moving the scan-type reactor at a predetermined height above the substrate of the lower process chamber part.

In the atomic layer deposition method, in ejecting the reactant precursor, when the reactant precursor is ejected toward the substrate through the scan-type reactor, a purge gas is ejected from opposite side portions or a peripheral portion of an upper surface or a lower surface of the scan-type reactor to form a gas barrier between the scan-type reactor and the substrate.

In the atomic layer deposition method, in ejecting the reactant precursor, when the reactant precursor is ejected toward the substrate through the scan-type reactor, plasma is generated above or below the scan-type reactor.

In the atomic layer deposition method, in ejecting the reactant precursor, when the reactant precursor is ejected toward the substrate through the scan-type reactor, an unreacted reactant precursor, a reaction byproduct or a purge gas existing between the scan-type reactor and the substrate is exhausted through a gas exhaust portion formed in opposite side portions or a peripheral portion of an upper surface or a lower surface of the scan-type reactor.

In the atomic layer deposition method, the scan-type reactor is supported by the vacuum chamber and is configured to wait in a predetermined position outside each of the process chambers.

In the atomic layer deposition method, the scan-type reactor includes one or more scan-type reactors provided in each of the process chambers and driven independently or simultaneously through a connection member which interconnects the scan-type reactors.

In accordance with another aspect of the present invention, there is provided an atomic layer deposition method performed in an atomic layer deposition device in which a process chamber is positioned within a vacuum chamber. In the method, an upper process chamber part and a lower process chamber part of the process chamber are coupled to form a sealed reaction space, after a substrate and a mask are loaded into the process chamber. A raw material precursor is caused to be adsorbed onto the substrate by performing an atomic layer deposition process within the sealed reaction space. An inert reactant precursor introduced into the process chamber is caused to react with the raw material precursor on the substrate using a scan-type reactor, after the raw material precursor is adsorbed onto the substrate.

In accordance with another aspect of the present invention, there is provided an atomic layer deposition method performed in a stacking-type atomic layer deposition device in which two or more process chambers are stacked within a vacuum chamber. In the method, an upper process chamber part and a lower process chamber part of each of the process chambers are coupled to form a sealed reaction space, after a substrate and a mask are loaded into each of the process chambers. A raw material precursor is caused to be adsorbed onto the substrate by performing an atomic layer deposition process within the sealed reaction space. An inert reactant precursor introduced into each of the process chambers is caused to react with the raw material precursor on the substrate using a scan-type reactor, after the raw material precursor is adsorbed onto the substrate.

In the atomic layer deposition method, in causing the inert reactant precursor introduced into each of the process chambers to react with the raw material precursor, the upper process chamber part and the lower process chamber part are separated after the raw material precursor is adsorbed onto the substrate. The scan-type reactor is moved over the substrate of the upper process chamber part or the lower process chamber part. The inert reactant precursor is caused to react with the raw material precursor on the substrate by activating the inert reactant precursor using plasma, ultraviolet rays or infrared rays generated from the scan-type reactor.

In the atomic layer deposition method, in causing the inert reactant precursor to react with the raw material precursor, only the inert reactant precursor introduced into each of the process chambers and existing on the substrate is selectively activated using the plasma, the ultraviolet rays or the infrared rays and is caused to react with the raw material precursor.

In the atomic layer deposition method, in causing the inert reactant precursor to react with the raw material precursor, when the scan-type reactor is moved toward the substrate, the plasma is generated above the substrate through the scan-type reactor to activate the inert reactant precursor.

In the atomic layer deposition method, in causing the inert reactant precursor to react with the raw material precursor, when the scan-type reactor is moved toward the substrate, the ultraviolet rays or the infrared rays are irradiated toward the substrate through the scan-type reactor to activate the inert reactant precursor.

In the atomic layer deposition method, the inert reactant precursor is a substance which reacts with the raw material precursor when activated by plasma, ultraviolet rays or infrared rays.

In the atomic layer deposition method, when the upper process chamber part and the lower process chamber part are separated from each other after the raw material precursor is adsorbed to the substrate, the inert reactant precursor is diffused and introduced from the vacuum chamber into a space between the upper process chamber part and the lower process chamber part separated from each other.

In the atomic layer deposition method, when the upper process chamber part and the lower process chamber part are coupled to each other after the substrate is loaded into each of the process chambers, the inert reactant precursor is filled into the vacuum chamber.

In the atomic layer deposition method, the scan-type reactor is supported by the vacuum chamber and is configured to wait in a predetermined position outside each of the process chambers.

### Effects of the Invention

According to the present invention, for the purpose of atomic layer deposition, a plurality of unit process chambers for atomic layer deposition process each provided with an upper process chamber part and a lower process chamber part which can be separated from and coupled to each other is disposed in a stacked form, and a scan-type reactor for causing a reactant precursor to react with a raw material precursor while moving over a substrate, onto which the raw material precursor is adsorbed, is provided in each of the unit process chambers. This makes it possible to fundamentally eliminate an area of coexistence of the raw material precursor and the reaction precursor, thereby making unnecessary any additional process for removing films which may otherwise be deposited outside the substrate, prolonging a maintenance period, suppressing generation of particles and eventually improving the quality and productivity of films.

In addition, additional functions such as a heat treatment, a plasma treatment or the like can be selectively added to the scan-type reactor, thereby enabling formation of atomic layer films with various characteristics. This makes it possible to form atomic layer films of various characteristics and to provide films optimized for needs. This also makes it possible to reduce additional facilities, thereby saving incidental expenses and maintenance costs.

### BRIEF DESCRIPTION OF THE DRAWINGS

FIG. 1 is a three-dimensional perspective view of an atomic layer deposition device according to an embodiment of the present invention.

FIGS. 2A and 2B are detailed cross-sectional structural views of a process chamber according to the embodiment of the present invention.

FIGS. 3A to 3C are schematic configuration views of a cross-sectional structure of the process chamber according to an embodiment of the present invention, illustrating an atomic layer deposition process using a scan-type reactor.

FIG. 4 is a schematic configuration view illustrating a plurality of scan-type reactors which are driven together through a connection member according to the embodiment of the present invention.

FIGS. 5A and 5B are schematic configuration views of a cross-sectional structure of the scan-type reactor and the process chamber according to the embodiment of the present invention, in which a process gas is ejected from the scan-type reactor.

FIGS. 5C to 5E are schematic configuration views of a cross-sectional structure of the scan-type reactor and the process chamber according to the embodiment of the present invention, in which a plasma process can be performed.

FIGS. 5F and 5G are schematic configuration views of a cross-sectional structure of the scan-type reactor and the process chamber according to the embodiment of the present invention, in which a process gas and a purge gas are simultaneously ejected from a lower portion of the scan-type reactor.

FIGS. 5H and 5I are schematic configuration views of a cross-sectional structure of the scan-type reactor and the process chamber according to the embodiment of the present invention, in which a process gas and a purge gas are simultaneously ejected from a lower portion of the scan-type reactor and in which a plasma process can be performed.

FIG. 5J is a schematic configuration view of a cross-sectional structure of the scan-type reactor and the process chamber according to the embodiment of the present invention, in which a heat treatment process can be performed with respect to a substrate.

FIGS. 6A to 6C are schematic configuration views of a cross-sectional structure of a process chamber according to another embodiment of the present invention, illustrating an atomic layer deposition process using a scan-type reactor.

FIGS. 7A and 7B are schematic configuration views of a cross-sectional structure of the scan-type reactor and the process chamber according to the another embodiment of the present invention, in which an atomic layer film forming process using plasma is performed in the scan-type reactor.

FIGS. 7C and 7D are schematic configuration views of a cross-sectional structure of the scan-type reactor and the process chamber according to the another embodiment of the present invention, in which an atomic layer film forming process using ultraviolet rays or infrared rays is performed in the scan-type reactor.

### BEST MODE FOR CARRYING OUT THE INVENTION

An operation principle of the present invention will now be described in detail with reference to the accompanying drawings.

In describing the present invention herein below, the detailed descriptions of well-known functions or configurations will be omitted if it is determined that the detailed descriptions of well-known functions or configurations may unnecessarily make obscure the spirit of the present invention. The terms to be described later are defined in view of the functions exercised in the present invention and may vary depending on the intention of a user or an operator, the practice or the like. Thus, the definition of terms shall be made based on the overall contents of the subject specification.

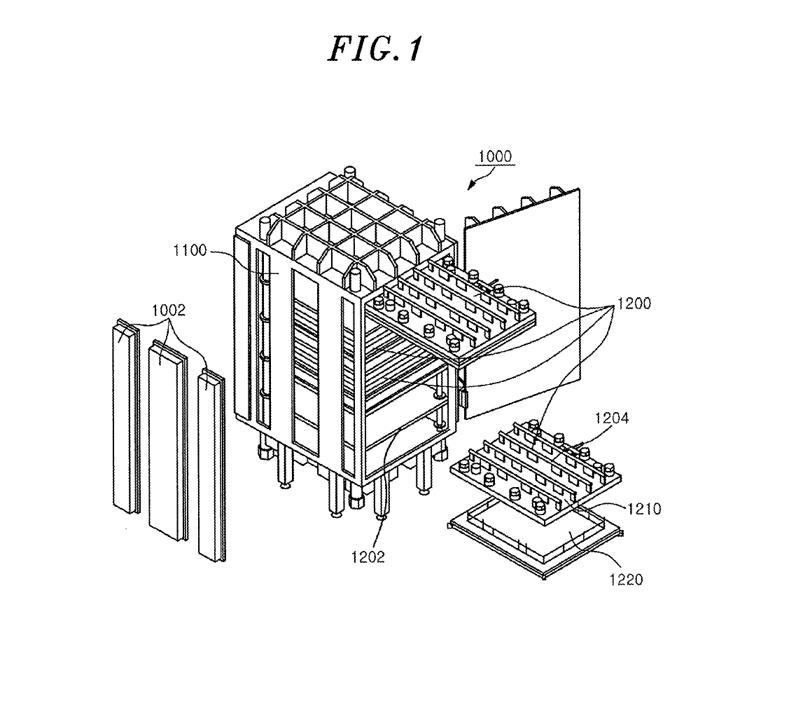

FIG. 1 is a three-dimensional perspective view of an atomic layer deposition device according to an embodiment of the present invention. The atomic layer deposition device 1000 may include a plurality of process chambers 1200 and a vacuum chamber 1100 which accommodates the process chambers 1200.

Hereinafter, a structure of the atomic layer deposition device 1000 according to the present invention will be described in detail with reference to FIG. 1.

First, the process chambers 1200 are chambers capable of performing an atomic layer deposition process with respect to a substrate. Each of the process chambers 1200 is configured to have an independent space. The process chambers 1200 are accommodated within the vacuum chamber 1100 while being stacked in a vertical direction. Each of the process chambers 1200 may include an upper process chamber part 1210 whose position is fixed when loaded into the vacuum chamber 1100 and a lower process chamber part 1220 which is moved up or down by a moving unit provided in the vacuum chamber 1100 and is coupled to or separated from the upper process chamber part 1210.

In the process chambers 1200, only a space capable of performing an optimal atomic layer deposition process is secured using the configuration in which the lower process chamber part 1220 is coupled to or separated from the upper process chamber part 1210. Thus, the process chambers 1200 may be designed so as to minimize the volume of the atomic layer deposition device.

Furthermore, the process chambers 1200 can be loaded into or unloaded from the vacuum chamber 1100 in cooperation with guide portions 1204 installed in an upper portion or a side surface of the vacuum chamber 1100. When loaded to a reference position within the vacuum chamber 1100, each of the process chambers 1200 may be fixed by adjusting the guide portions 1204.

Next, the vacuum chamber 1100 may include multi-stage support portions 1202, which are capable of stacking the process chambers in an up-down direction within the vacuum chamber 1100, and guide portions 1204. The vacuum chamber 1100 maintains a vacuum state so that an atomic layer deposition process can be performed in each of the process chambers 1200.

That is to say, the vacuum chamber 1100 supports the process chambers 1200 which are stacked and disposed within the vacuum chamber 1100 and which are configured to be separated or coupled to perform an atomic layer deposition process. The vacuum chamber 1100 enables a substrate to be carried into or out of each of the process chambers. The vacuum chamber 1100 can minimize the influence of an external force applied to the process chambers 1200 from an ambient air or an environment having a pressure difference with respect to the process chambers 1200.

Accordingly, in the case of using the structure in which the process chambers 1200 for independently performing an atomic layer deposition process are stacked within the vacuum chamber 1100 in an up-down direction as illustrated in FIG. 1, films are simultaneously formed on a plurality of substrates within the process chambers 1200.

This enables the atomic layer deposition device 1000 of the present invention to enjoy the productivity several times as high as the productivity of a conventional single-substrate-type deposition device.

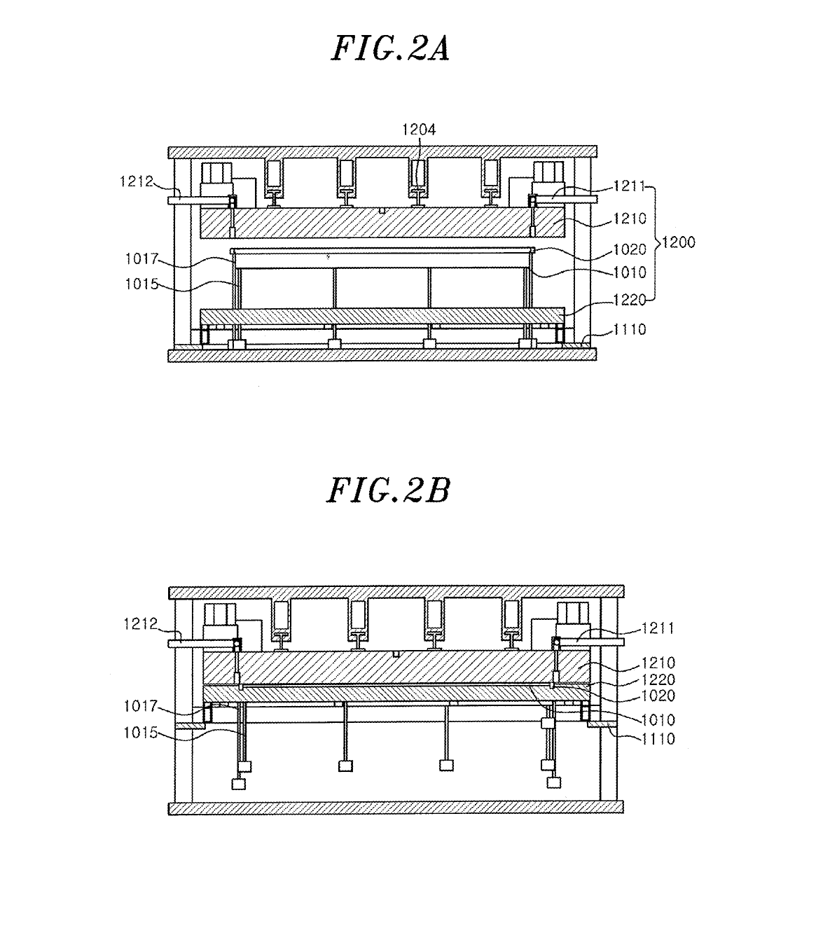

FIGS. 2A and 2B illustrate a detailed cross-sectional structure of the process chamber according to the embodiment of the present invention.

First, FIG. 2A illustrates a state in which the lower process chamber part 1220 is moved down to open the process chamber 1200 for loading of a substrate 1010 and a mask 1020 into the process chamber 1200.

Referring to FIG. 2A, the lower process chamber part 1220 is moved down in the up-down direction away from the upper process chamber part 1210 by a moving unit 1110 so that the process chamber 1200 is opened. In this state, the substrate 1010 and the mask 1020 are sequentially loaded onto a substrate support portion 1015 and a mask support portion 1017 provided within the process chamber 1200. At this time, the upper process chamber part 1210 is fixed to and supported by the vacuum chamber 1100. The lower process chamber part 1220 can be moved in the up-down direction with respect to the vacuum chamber 1100 by the moving unit 1110 provided in the vacuum chamber 1100.

After the substrate 1010 and the mask 1020 are respectively loaded onto the substrate support portion 1015 and the mask support portion 1017 as described above, the lower process chamber part 1220 is moved up by the moving unit 1110. The substrate 1010 and the mask 1020 are sequentially mounted on the lower process chamber part 1220. Then, as illustrated in FIG. 2B, the lower process chamber part 1220 is finally coupled to the upper process chamber part 1210.

In this case, the loading of the substrate 1010 and the mask 1020 may be individually performed in each of the process chambers 1200 or may be simultaneously performed in a state in which the process chambers 1200 existing within the vacuum chamber 1100 are opened.

Next, FIG. 2B illustrates a state in which the substrate 1010 and the mask 1020 are loaded into the process chamber 1200 and in which the lower process chamber part 1220 is move up and coupled to the upper process chamber part 1210 in order to perform a process.

Referring to FIG. 2B, after the substrate 1010 and the mask 1020 are loaded with the process chamber 1200 kept opened, the lower process chamber part 1220 is moved up by the moving unit 1110 and is coupled to the upper process chamber part 1210. This makes it possible to form a sealed reaction space in the process chamber 1200.

After the upper process chamber part 1210 and the lower process chamber part 1220 are coupled to each other in this way to form the sealed reaction space in which a process can be performed, a required gas is introduced through a process gas supply portion 1212 as a process proceeds. Thus, an atomic layer deposition process can be performed with respect to the substrate 1010.

After the atomic layer deposition process with respect to the substrate 1010 is completed in a state in which the upper process chamber part 1210 and the lower process chamber part 1220 are coupled to each other as described above, the lower process chamber part 1220 is moved down by the moving unit 1110 and is separated from the upper process chamber part 1210. In this state, the processed substrate 1010 is unloaded out from the process chamber 1200.

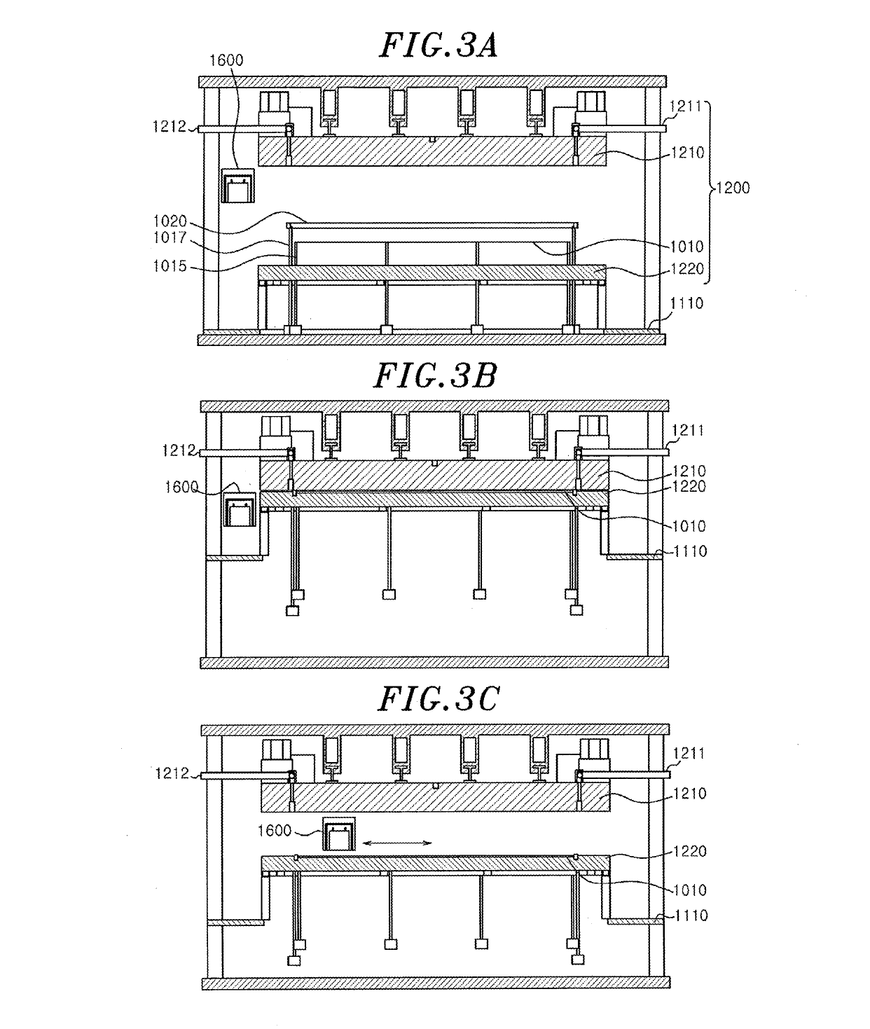

FIGS. 3A to 3C illustrate a cross-sectional structure of the process chamber according to the embodiment of the present invention, in which an atomic layer deposition process using a scan-type reactor is performed.

Hereinafter, an operation concept of an atomic layer deposition process using a scan-type reactor 1600 will be described with reference to FIGS. 3A to 3C.

First, as illustrated in FIG. 3A, the lower process chamber part 1220 is moved down in the vertical direction away from the upper process chamber part 1210 by the moving unit 1110 so that the process chamber 1200 is opened. In this state, the substrate 1010 and the mask 1020 are sequentially loaded onto the substrate support portion 1015 and the mask support portion 1017 installed within the process chamber 1200, respectively.

If the substrate 1010 and the mask 1020 are normally loaded in this way, as illustrated in FIG. 3B, the lower process chamber part 1220 is moved up by the moving unit 1110 and is coupled to the upper process chamber part 1210. By virtue of this coupling, there is formed a sealed reaction space in which an atomic layer deposition process can be performed. Then, process gases required in the atomic layer deposition process are sequentially introduced through the gas supply portion 1212. This makes it possible to perform the atomic layer deposition process with respect to the substrate 1010.

At this time, in the atomic layer deposition process using the scan-type reactor 1600 according to the embodiment of the present invention, only a step of allowing a raw material precursor to be adsorbed is performed in a state in which the upper process chamber part 1210 and the lower process chamber part 1220 of the process chamber 1200 are coupled to each other. After the step of allowing the raw material precursor to be adsorbed is completed, the upper process chamber part 1210 and the lower process chamber part 1220 are separated from each other. Thereafter, a reactant precursor reaction step is performed using the scan-type reactor 1600.

As an example of a method of allowing the raw material precursor to be adsorbed within the reaction space, as illustrated in FIG. 3B, a gas is supplied through the gas supply portion 1212 provided in the outer periphery of an top surface of the upper process chamber part 1210, thereby ejecting the raw material precursor toward the substrate 1010. If the raw material precursor is sufficiently ejected toward the substrate 1010, a purge gas is supplied from the gas supply portion 1212. Thus, the raw material precursor of a physical adsorption layer physically attached to the substrate 1010 is separated from the substrate 1010. This makes it possible to obtain a single molecular layer of the raw material precursor.

At the step of allowing the raw material precursor to be adsorbed within the process chamber 1200, there has been described an example where the gas supply portion 1212 is provided at a side of the upper process chamber part 1210 to horizontally eject the raw material precursor from a side of the substrate 1010. However, this is nothing more than one example. The gas supply portion 1212 may be provided in the central portion of the upper process chamber part 1210 in the form of a shower head or a diffuser so that the raw material precursor is ejected in a direction perpendicular to the substrate 1010.

After the adsorption of the raw material precursor is completed in a state in which the upper process chamber part 1210 and the lower process chamber part 1220 are coupled to each other, as illustrated in FIG. 3C, the upper process chamber part 1210 and the lower process chamber part 1220 are separated again. Thereafter, an atomic layer film is formed on the substrate 1010 by ejecting a reactant precursor toward the substrate 1010 while unidirectionally moving or reciprocating the scan-type reactor 1600 in a direction parallel to the substrate 1010.

A process of forming an atomic layer film using the aforementioned scan-type reactor 1600 will be described in more detail. After the raw material precursor adsorption step and the purge step are completed in a state in which the upper process chamber part 1210 and the lower process chamber part 1220 are coupled to each other, the lower process chamber part 1220 is moved down by the moving unit 1110 and is separated from the upper process chamber part 1210. Then, the lower process chamber part 1220 is located in a predetermined position lower than the scan-type reactor 1600 positioned at one side of the process chamber 1200. At this time, the position of the lower process chamber part 1220 may be set at a predetermined optimal position so that the scan-type reactor 1600 can eject a reactant precursor while horizontally moving over the substrate 1010 of the lower process chamber part 1220.

In case where the lower process chamber part 1220 is moved down to the predetermined position where the scan-type reactor 1600 can move in a direction parallel to the substrate 1010 of the lower process chamber part 1220 and the scan-type reactor 1600 is made movable, the reactant precursor is ejected toward the substrate through a gas supply portion (not shown) formed in the lower portion of the scan-type reactor 1600 while unidirectionally moving or reciprocating the scan-type reactor 1600 in a direction parallel to the substrate 1010. The reactant precursor ejected from the scan-type reactor 1600 makes chemical reaction with the raw material precursor adsorbed onto the substrate 1010, thereby forming an atomic layer film.

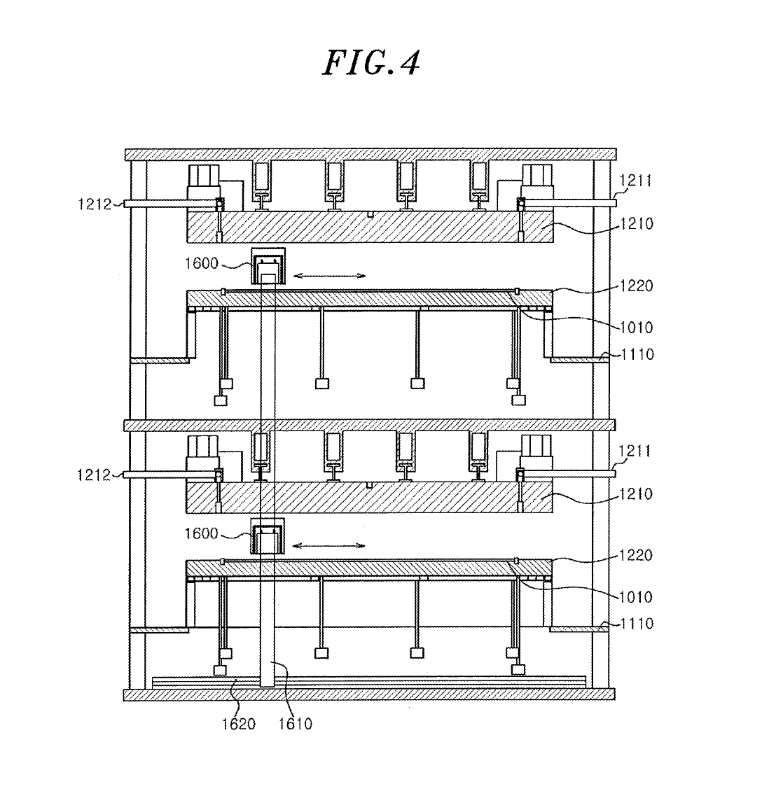

At this time, the scan-type reactor 1600 described above may be independently driven by an independent drive unit in each of the process chambers 1200. Alternatively, as illustrated in FIG. 4, a plurality of scan-type reactors 1600 may be interconnected through a connection member 1610 such as a connection bar or the like and may be simultaneously driven by a common reactor moving unit 1620 which controls the movement of the connection member 1610. In the embodiment of the present invention, there has been described an example where the scan-type reactor is operated in the atomic layer deposition device of the type in which the process chambers are stacked within the vacuum chamber. However, the atomic layer deposition process using the scan-type reactor may be equally applicable to a case where one process chamber exists within the vacuum chamber.

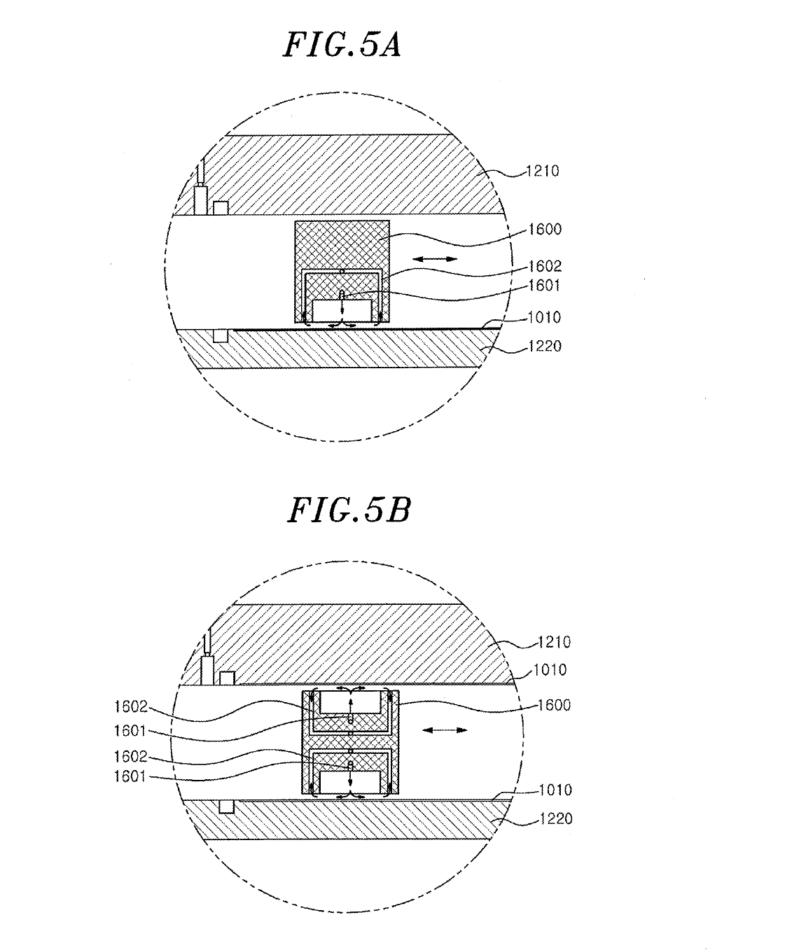

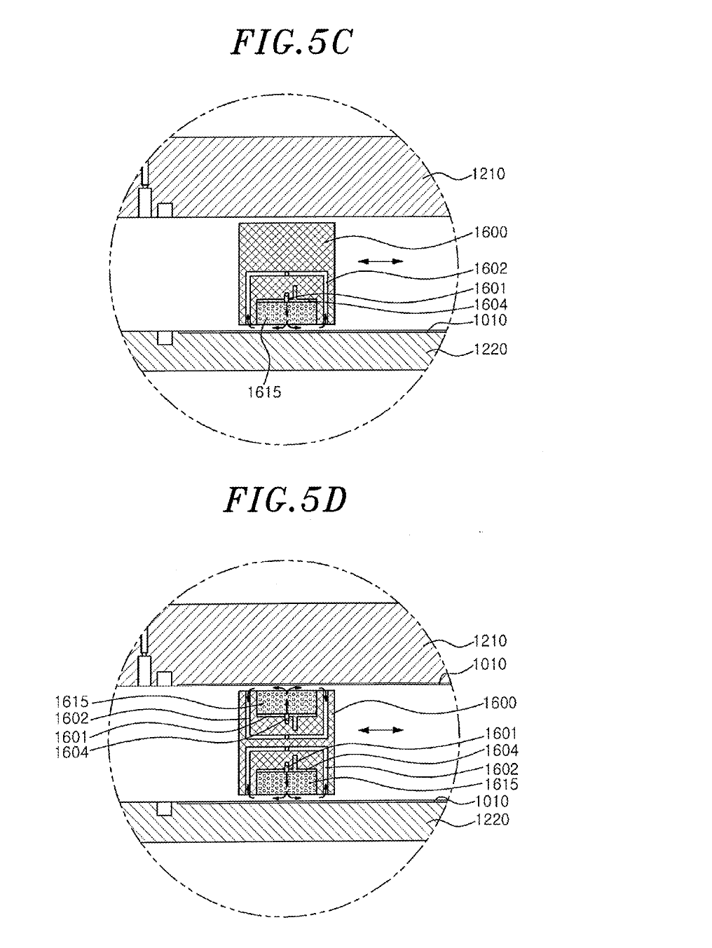

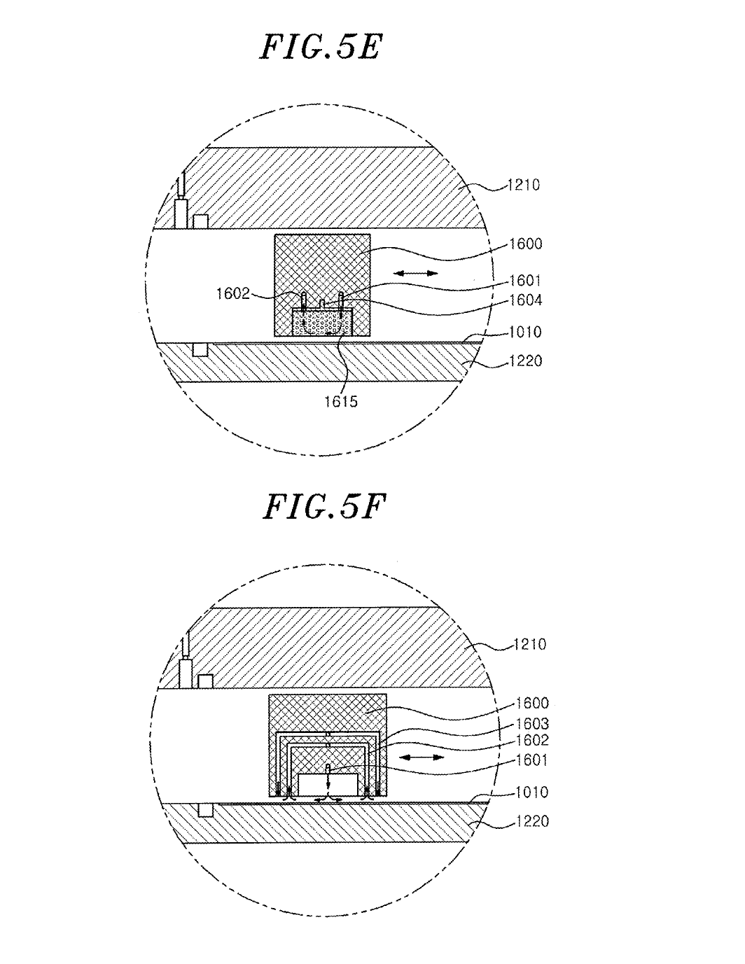

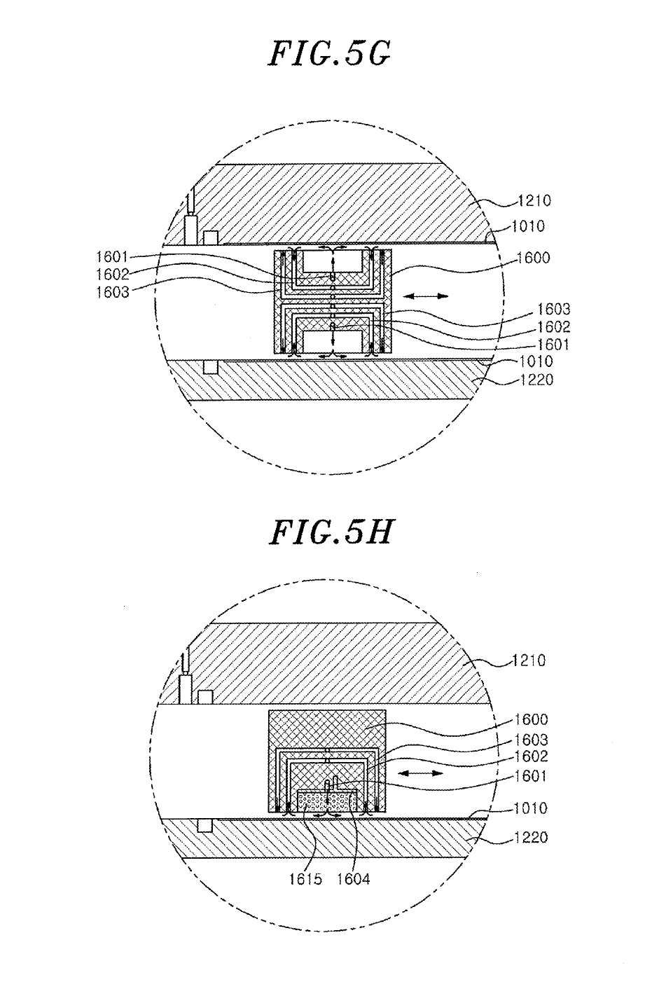

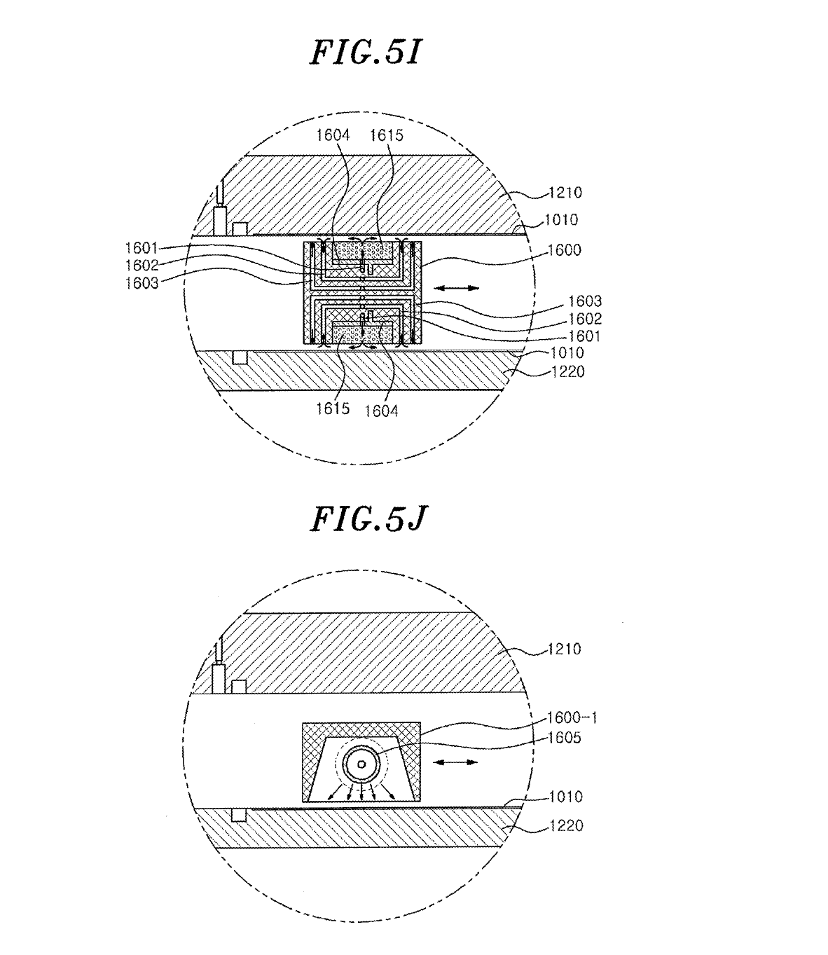

The atomic layer deposition process using the scan-type reactor described above will be described in more detail with reference to FIGS. 5A to 5J.

FIG. 5A is schematic configuration view of a cross-sectional structure of the scan-type reactor and the process chamber according to the embodiment of the present invention, in which a process gas containing a reactant precursor is ejected from the scan-type reactor.

Referring to FIG. 5A, the reactant precursor is supplied in a direction perpendicular to the substrate 1010 through a gas supply portion 1601 formed at the central portion of a lower surface of the scan-type reactor 1600. The reactant precursor failing to react with the raw material precursor and remaining on the substrate is exhausted through a gas exhaust portion 1602 formed in the opposite side portions or the peripheral portion of the lower surface of the scan-type reactor 1600.

Hereinafter, the operation will be described. After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210. Then, the lower process chamber part 1220 is located in a predetermined position lower than the scan-type reactor 1600 positioned at one side of the process chamber 1200. At this time, the position of the lower process chamber part 1220 may be set at a predetermined optimal position so that the scan-type reactor 1600 can eject the reactant precursor while horizontally moving over the substrate 1010 of the lower process chamber part 1220.

As the lower process chamber part 1220 is moved down to the predetermined position where the scan-type reactor 1600 can move in a direction parallel to the substrate 1010 of the lower process chamber part 1220, the scan-type reactor 1600 waiting at the predetermined position is made movable. Then, the scan-type reactor 1600 ejects the reactant precursor while moving over the substrate 1010 of the lower process chamber part 1220, onto which the raw material precursor is adsorbed.

That is to say, the reactant precursor is uniformly ejected toward the substrate 1010 through the gas supply portion 1601 formed in the central portion of the lower surface of the scan-type reactor 1600, while moving the scan-type reactor 1600 at a predetermined moving speed over the substrate 1010 onto which the raw material precursor is adsorbed. The reactant precursor ejected from the scan-type reactor 1600 chemically reacts with the raw material precursor adsorbed onto the substrate 1010, thereby forming an atomic layer film.

At this time, the scan-type reactor 1600 can perform the ejection of the reactant precursor while unilaterally moving or reciprocating over the substrate 1010 of the lower process chamber part 1220 in the horizontal direction. Furthermore, for the purpose of assuring smooth reaction of the reactant precursor and improving film characteristics, the lower process chamber part 1220 may be given a heater function so as to adjust the temperature of the substrate 1010. This enables the lower process chamber part 1220 to serve as a susceptor.

In the atomic layer deposition using the scan-type reactor 1600, when the reactant precursor is ejected through the scan-type reactor 1600, the raw material precursor and the reactant precursor chemically react on the substrate 1010, thereby forming an atomic layer film. The reactant precursor failing to react with the raw material precursor can be exhausted, along with the movement of the scan-type reactor 1600, through the gas exhaust portion 1602 formed in the opposite side portions of the lower surface of the scan-type reactor 1600. Accordingly, it is possible to remove the reactant precursor without having to perform an additional purge step for removing the reactant precursor failing to react with the raw material precursor and remaining on the substrate 1010.

In the structure of the scan-type reactor 1600 illustrated in FIG. 5A, there has been described an example where the substrate 1010 is mounted on only the lower process chamber part 1220 and the reactant precursor is ejected toward only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 1600.

In this case, as illustrated in FIG. 5B, gas supply portions 1601 for ejecting the reactant precursor and gas exhaust portions 1602 may be similarly formed in the upper portion and the lower portion of the scan-type reactor 1600 so that atomic layer films can be simultaneously formed on the substrate 1010 of the upper process chamber part 1210 and the substrate 1010 of the lower process chamber part 1220.

Next, FIG. 5C is a schematic configuration view of a cross-sectional structure of the scan-type reactor and the process chamber according to the embodiment of the present invention, in which a plasma process can be performed.

Referring to FIG. 5C, the reactant precursor is supplied in a direction perpendicular to the substrate 1010 through a gas supply portion 1601 formed in a central portion of a lower portion of the scan-type reactor 1600. The reactant precursor failing to react with the raw material precursor and remaining on the substrate 1010 is exhausted through a gas exhaust portion 1602 formed in the opposite side portions of the lower surface of the scan-type reactor 1600. In the structure illustrated in FIG. 5C, unlike the structure illustrated in FIG. 5A, an electrode 1604 for generating plasma is disposed in the lower portion of the scan-type reactor 1600 so that plasma can be used in the atomic layer deposition process using the scan-type reactor 1600.

Hereinafter, the operation will be described. After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210.

Then, the lower process chamber part 1220 is located in a predetermined position lower than the scan-type reactor 1600 positioned on one side of the process chamber 1200.

As the lower process chamber part 1220 is moved down to the predetermined position where the scan-type reactor 1600 can move in a direction parallel to the substrate 1010 of the lower process chamber part 1220, the scan-type reactor 1600 waiting at the predetermined position is made movable. Then, the scan-type reactor 1600 ejects the reactant precursor while moving over the substrate 1010 of the lower process chamber part 1220, onto which the raw material precursor is adsorbed.

That is to say, the reactant precursor is uniformly ejected toward the substrate 1010 through the gas supply portion 1601 formed in the central portion of the lower surface of the scan-type reactor 1600, while moving the scan-type reactor 1600 at a predetermined moving speed over the substrate 1010 onto which the raw material precursor is adsorbed. The reactant precursor ejected from the scan-type reactor 1600 chemically reacts with the raw material precursor adsorbed onto the substrate 1010, thereby forming an atomic layer film.

At the time point at which the reactant precursor is ejected by the scan-type reactor 1600, electric power is supplied to the plasma-generating electrode 1604 provided in the lower portion of the scan-type reactor 1600 to generate plasma 1615 above the substrate 1010. If the reactant precursor is activated by the plasma 1615, the reactant precursor chemically reacts with the raw material precursor, thereby forming an atomic layer film.

In the structure of the scan-type reactor 1600 illustrated in FIG. 5C, there has been described an example where the substrate 1010 is mounted on only the lower process chamber part 1220 and the reactant precursor is ejected toward only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 1600.

In this case, as illustrated in FIG. 5D, gas supply portions 1601 for ejecting the reactant precursor and gas exhaust portions 1602 may be similarly formed in the upper portion and the lower portion of the scan-type reactor 1600 so that atomic layer films can be simultaneously formed on the substrate 1010 of the upper process chamber part 1210 and the substrate 1010 of the lower process chamber part 1220 using the plasma 1615.

In the scan-type reactor 1600 using the plasma 1615 illustrated in FIG. 5C, there has been described a structure in which the gas supply portion 1601 is formed in the central portion and the gas exhaust portion 1602 is formed in the opposite side portions so that the reactant precursor is ejected from the central portion of the scan-type reactor 1600 and is exhausted through the opposite side portions. However, the gas supply portion 1601 and the gas exhaust portion 1602 may be formed in the opposite side portions of the scan-type reactor 1600 in a mutually-symmetrical relationship.

In this case, as illustrated in FIG. 5E, the reactant precursor is ejected from the gas supply portion 1601 formed in one side portion of the lower surface of the scan-type reactor 1600. The reactant precursor failing to react with the raw material precursor and remaining on the substrate 1010 can be exhausted through the gas exhaust portion 1602 formed in the other side portion of the lower surface of the scan-type reactor 1600.

Next, FIG. 5F is schematic configuration view of a cross-sectional structure of the scan-type reactor and the process chamber according to an embodiment of the present invention, in which a process gas and a purge gas are simultaneously ejected from a lower portion of the scan-type reactor.

Referring to FIG. 5F, the reactant precursor is supplied in a direction perpendicular to the substrate through the gas supply portion 1601 formed in the central portion of the scan-type reactor 1600. The reactant precursor failing to react with the raw material precursor and remaining on the substrate 1010 is exhausted through the gas exhaust portion 1602 formed in the opposite side portions of the lower surface of the scan-type reactor 1600. In the structure illustrated in FIG. 5F, unlike the structure illustrated in FIG. 5A, a purge gas supply portion 1603 is additionally formed in the opposite side portions or the peripheral portion of the lower surface of the scan-type reactor 1600 at the outer side of the gas exhaust portion 1602. When ejecting the reactant precursor, a purge gas is also ejected to form a gas barrier having an air curtain effect.

Hereinafter, the operation will be described. After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210. Then, the lower process chamber part 1220 is located in a predetermined position lower than the scan-type reactor 1600 positioned on one side of the process chamber 1200.

As the lower process chamber part 1220 is moved down to the predetermined position where the scan-type reactor 1600 can move in a direction parallel to the substrate 1010 of the lower process chamber part 1220, the scan-type reactor 1600 waiting at the predetermined position is made movable. Then, the scan-type reactor 1600 ejects the reactant precursor while moving over the substrate 1010 of the lower process chamber part 1220, onto which the raw material precursor is adsorbed.

That is to say, the reactant precursor is uniformly ejected toward the substrate 1010 through the gas supply portion 1601 formed in the central portion of the lower surface of the scan-type reactor 1600, while moving the scan-type reactor 1600 at a predetermined moving speed over the substrate 1010 onto which the raw material precursor is adsorbed. The reactant precursor ejected from the scan-type reactor 1600 makes chemical reaction with the raw material precursor adsorbed onto the substrate 1010, thereby forming an atomic layer film.

In the structure illustrated in FIG. 5F, when the reactant precursor is ejected by the scan-type reactor 1600, the purge gas is also ejected through the purge gas supply portion 1603 formed in the lower portion of the scan-type reactor 1600 at the outer side of the gas exhaust portion 1602.

By ejecting the purge gas in this way, the reactant precursor failing to react with the raw material precursor and remaining on the substrate 1010 of the lower process chamber part 1220 is separated from the substrate 1010 and is exhausted through the gas exhaust portion 1602. Moreover, the purge gas ejected from the purge gas supply portion 1603 in a direction perpendicular to the substrate 1010 serves as an air curtain. Thus, the reactant precursor ejected from the gas supply portion 1601 toward the substrate 1010 and leaked toward the space between the scan-type reactor 1600 and the substrate 1010 is blocked by the purge gas and is prevented from being leaked to the outside of the process chamber 1200.

In the structure of the scan-type reactor 1600 illustrated in FIG. 5F, there has been described an example where the substrate 1010 is mounted on only the lower process chamber part 1220 and the reactant precursor is ejected toward only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 1600.

In this case, as illustrated in FIG. 5G, gas supply portions 1601 for ejecting the reactant precursor, gas exhaust portions 1602 for exhausting the reactant precursor and purge gas supply portions 1603 for ejecting the purge gas may be similarly formed in the upper portion and the lower portion of the scan-type reactor 1600 so that atomic layer films can be simultaneously formed on the substrate 1010 of the upper process chamber part 1210 and the substrate 1010 of the lower process chamber part 1220.

Next, FIG. 5H is a schematic configuration view of a cross-sectional structure of the scan-type reactor and the process chamber according to the embodiment of the present invention, in which a process gas and a purge gas are simultaneously ejected from the lower portion of the scan-type reactor and in which a plasma process can be performed.

Referring to FIG. 5H, the reactant precursor is supplied in a direction perpendicular to the substrate 1010 through the gas supply portion 1601 formed in the central portion of the scan-type reactor 1600. The reactant precursor failing to react with the raw material precursor and remaining on the substrate 1010 is exhausted through the gas exhaust portion 1602 formed in the opposite side portions of the lower surface of the scan-type reactor 1600. In the structure illustrated in FIG. 5H, an electrode 1604 for generating plasma 1615 is disposed in the lower portion of the scan-type reactor 1600 so that the plasma 1615 can be used in an atomic layer deposition process using the scan-type reactor 1600. Furthermore, a purge gas supply portion 1603 is additionally formed in the opposite side portions of the lower surface of the scan-type reactor 1600 at the outer side of the gas exhaust portion 1602. When ejecting the reactant precursor, a purge gas is also ejected to form an air curtain.

Hereinafter, the operation will be described. After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210. Then, the lower process chamber part 1220 is located in a predetermined position lower than the scan-type reactor 1600 positioned on one side of the process chamber 1200.

As the lower process chamber part 1220 is moved down to the predetermined position where the scan-type reactor 1600 can move in a direction parallel to the substrate 1010 of the lower process chamber part 1220, the scan-type reactor 1600 waiting at the predetermined position is made movable. Then, the scan-type reactor 1600 ejects the reactant precursor while moving over the substrate 1010 of the lower process chamber part 1220, onto which the raw material precursor is adsorbed.

That is to say, the reactant precursor is uniformly ejected toward the substrate 1010 through the gas supply portion 1601 formed in the central portion of the lower surface of the scan-type reactor 1600, while moving the scan-type reactor 1600 at a predetermined moving speed over the substrate 1010 onto which the raw material precursor is adsorbed. The reactant precursor ejected from the scan-type reactor 1600 chemically reacts with the raw material precursor adsorbed onto the substrate 1010, thereby forming an atomic layer film.

In the structure illustrated in FIG. 5H, at the time point at which the reactant precursor is ejected by the scan-type reactor 1600, electric power is supplied to the plasma-generating electrode 1604 formed in the lower portion of the scan-type reactor 1600 to generate plasma 1615 above the substrate 1010. An atomic layer film is formed by chemical reaction between the raw material precursor and the reactant precursor using the plasma 1615.

Furthermore, in the structure illustrated in FIG. 5H, when the reactant precursor is ejected by the scan-type reactor 1600, the purge gas is also ejected through the purge gas supply portion 1603 formed in the lower portion of the scan-type reactor 1600 at the outer side of the gas exhaust portion 1602.

By ejecting the purge gas in this way, the reactant precursor failing to react with the raw material precursor and remaining on the substrate 1010 of the lower process chamber part 1220 is separated from the substrate 1010 and is exhausted through the gas exhaust portion 1602. Moreover, the purge gas ejected from the purge gas supply portion 1603 in a direction perpendicular to the substrate 1010 serves as an air curtain. Thus, the reactant precursor ejected from the gas supply portion 1601 toward the substrate 1010 and leaked toward the space between the scan-type reactor 1600 and the substrate 1010 is blocked by the purge gas and is prevented from being leaked to the outside of the process chamber 1200.

In the structure of the scan-type reactor 1600 illustrated in FIG. 5H, there has been described an example where the substrate 1010 is mounted on only the lower process chamber part 1220 and the reactant precursor is ejected toward only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 1600.

In this case, as illustrated in FIG. 5I, gas supply portions 1601 for ejecting the reactant precursor, gas exhaust portions 1602 for exhausting the reactant precursor and purge gas supply portions 1603 for ejecting the purge gas may be similarly formed in the upper portion and the lower portion of the scan-type reactor 1600 so that atomic layer films can be simultaneously formed on the substrate 1010 of the upper process chamber part 1210 and the substrate 1010 of the lower process chamber part 1220.

Next, FIG. 5J is a schematic configuration view of a cross-sectional structure of the scan-type reactor and the process chamber according to an embodiment of the present invention, in which a heat treatment process can be performed with respect to the substrate.

The scan-type reactor 1600-1 illustrated in FIG. 5J is not a reactor for ejecting a reactant precursor but a reactor which includes a heat treatment unit 1605 for performing a heat treatment or a ultraviolet treatment with respect to a substrate 1010 through the use of a heating wire or a lamp before, during and after a film forming process. The scan-type reactor 1600-1 is configured to perform the cleaning of a substrate 1010, the surface modification of a film, or the change of physical properties of a film.

Hereinafter, the operation will be described. The lower process chamber part 1220 is moved down by the moving unit 1110 to be separated from the upper process chamber part 1210. Then, the lower process chamber part 1220 is located in a predetermined position lower than the scan-type reactor 1600 positioned on one side of the process chamber 1200.

As the lower process chamber part 1220 is moved down to the predetermined position where the scan-type reactor 1600-1 can move in a direction parallel to the substrate 1010 of the lower process chamber part 1220, the scan-type reactor 1600-1 waiting at the predetermined position is made movable. Then, a heat treatment or an ultraviolet treatment is performed while moving the scan-type reactor 1600-lover the substrate 1010 of the lower process chamber part 1220 or the film deposited on the substrate 1010. In this case, as the heat treatment unit 1605 for performing the heat treatment, it may be possible to use, for example, an infrared lamp. As the ultraviolet treatment unit, it may be possible to use an ultraviolet lamp.

Hereinafter, the arrangement and process cycle of the scan-type reactor 1600-1 for a heat treatment or an ultraviolet treatment will be described. The scan-type reactor 1600-1 may be additionally disposed in close proximity to the scan-type reactor 1600. The scan-type reactor 1600-1 can perform a simultaneous moving work and a simultaneous process with the scan-type reactor 1600 for ejecting the reactant precursor, a simultaneous moving work and a cyclic process with the scan-type reactor 1600, and an individual moving work and an individual process with the scan-type reactor 1600.

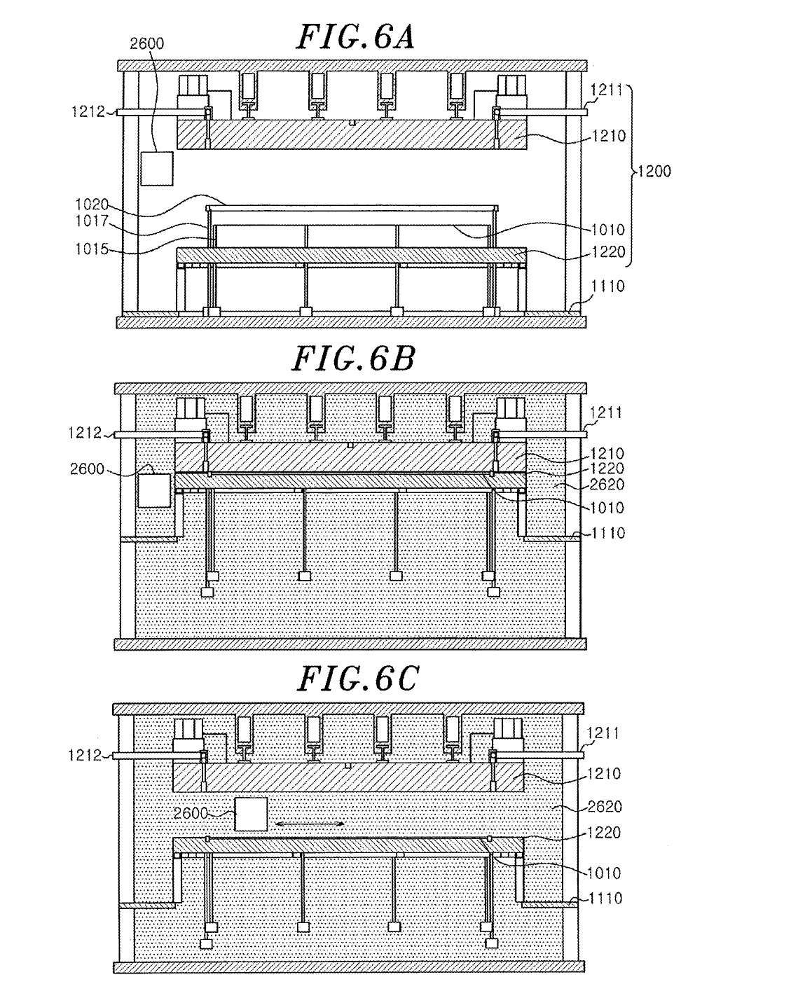

FIGS. 6A to 6C are schematic configuration views of a cross-sectional structure of a process chamber according to another embodiment of the present invention, illustrating an atomic layer deposition process using a scan-type reactor.

Hereinafter, an operation concept of an atomic layer deposition process using a scan-type reactor 2600 will be described with reference to FIGS. 6A to 6C.

First, as illustrated in FIG. 6A, the lower process chamber part 1220 is moved down in the vertical direction away from the upper process chamber part 1210 by the moving unit 1110 and the process chamber 1200 is opened. In this state, the substrate 1010 and the mask 1020 are sequentially loaded onto the substrate support portion 1015 and the mask support portion 1017 installed within the process chamber 1200, respectively.

If the substrate 1010 and the mask 1020 are normally loaded in this way, as illustrated in FIG. 6B, the lower process chamber part 1220 is moved up by the moving unit 1110 and is coupled to the upper process chamber part 1210. By virtue of this coupling, there is formed a sealed reaction space in which an atomic layer deposition process can be performed. Then, process gases required in the atomic layer deposition process are sequentially introduced through the gas supply portion 1212. This makes it possible to perform the atomic layer deposition process with respect to the substrate 1010.

At this time, in the atomic layer deposition process using the scan-type reactor 2600 according to an embodiment of the present invention, only a step of allowing a raw material precursor to be adsorbed is performed in a state in which the upper process chamber part 1210 and the lower process chamber part 1220 of the process chamber 1200 are coupled to each other. After the step of allowing the raw material precursor to be adsorbed is completed, as illustrated in FIG. 60, the upper process chamber part 1210 and the lower process chamber part 1220 are separated from each other. Thereafter, a step of allowing the reactant precursor to react with the raw material precursor adsorbed onto the substrate 1010 is performed using the scan-type reactor 2600.

A process of forming an atomic layer film using the aforementioned scan-type reactor 2600 will be described in more detail. After the raw material precursor adsorption step and the purge step are completed in a state in which the upper process chamber part 1210 and the lower process chamber part 1220 are coupled to each other as illustrated in FIG. 6B, the lower process chamber part 1220 is moved down by the moving unit 1110 to be separated from the upper process chamber part 1210. Then, the lower process chamber part 1220 is located in a predetermined position lower than the scan-type reactor 1600 positioned on one side of the process chamber 1200. At this time, the position of the lower process chamber part 1220 may be set at a predetermined optimal position so that the scan-type reactor 2600 can horizontally move over the substrate 1010 of the lower process chamber part 1220.

In the embodiment illustrated in FIG. 6B, unlike the embodiment illustrated in FIG. 3B, the process chamber 1200 is filled with an inert reactant precursor 2620 under a predetermined pressure. In this state, after the step of allowing a raw material precursor to be absorbed onto the substrate 1010 is completed, when the lower process chamber part 1220 is separated from the upper process chamber part 1210, as illustrated in FIG. 6C, the inert reactant precursor 2620 is filled into the space between the upper process chamber part 1210 and the lower process chamber part 1220 separated from each other.

In the case of not using external specific energy such as plasma or ultraviolet rays, a substance that does not react with the raw material precursor adsorbed onto the substrate 1010 may be selected as the inert reactant precursor 2620. The inert reactant precursor 2620 may be filled into the vacuum chamber 1100 at the time point at which the upper process chamber part 1210 and the lower process chamber part 1220 are coupled to each other after the substrate 1010 and the mask 1020 are loaded into the process chamber 1200.

Unlike the scan-type reactor 1600 illustrated in FIG. 3A and provided with the gas supply portion for ejecting the reactant precursor and the purge gas, the scan-type reactor 2600 may be provided with a plasma-generating electrode or an ultraviolet irradiation device, such as an ultraviolet lamp or the like, which can supply energy such as plasma or ultraviolet rays to the substrate 1010 in order to selectively activate the inert reactant precursor 2620 existing within the process chamber 1200.

Accordingly, if the lower process chamber part 1220 is separated from the upper process chamber part 1210 and is moved down to a predetermined position where the scan-type reactor 2600 located on one side of the process chamber 1200 can horizontally move over the substrate 1010 of the lower process chamber part 1220, the scan-type reactor 2600 supplies energy such as plasma or ultraviolet rays to the substrate 1010 while moving over the substrate 1010, thereby selectively activating only the inert reactant precursor 2620 existing on the substrate 1010. Thus, the inert reactant precursor 2620 chemically reacts with the raw material precursor adsorbed onto the substrate 1010 to form an atomic layer film.

At this time, the scan-type reactor 2600 described above may be independently driven by an independent drive unit in each of the process chambers 1200.

Alternatively, as illustrated in FIG. 4, a plurality of scan-type reactors 2600 may be interconnected through a connection member 1610 such as a connection bar or the like and may be simultaneously driven. In the embodiment of the present invention, there has been described an example where the scan-type reactor is operated in the atomic layer deposition device of the type in which the process chambers are stacked within the vacuum chamber. However, the atomic layer deposition process using the scan-type reactor may be equally applicable to a case where one process chamber exists within the vacuum chamber.

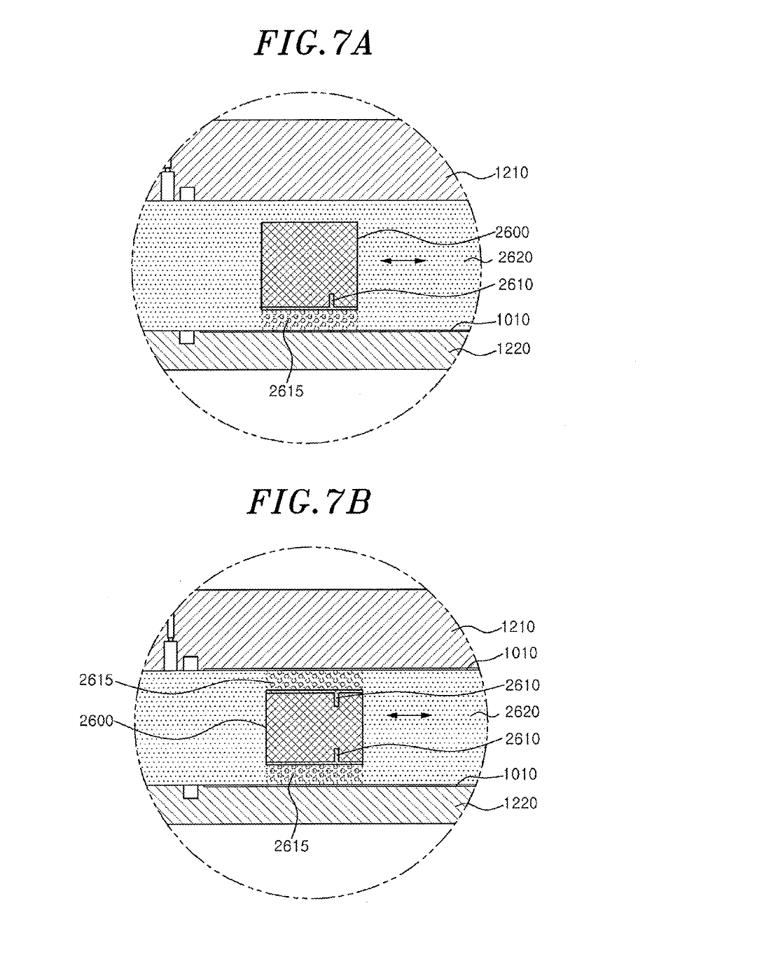

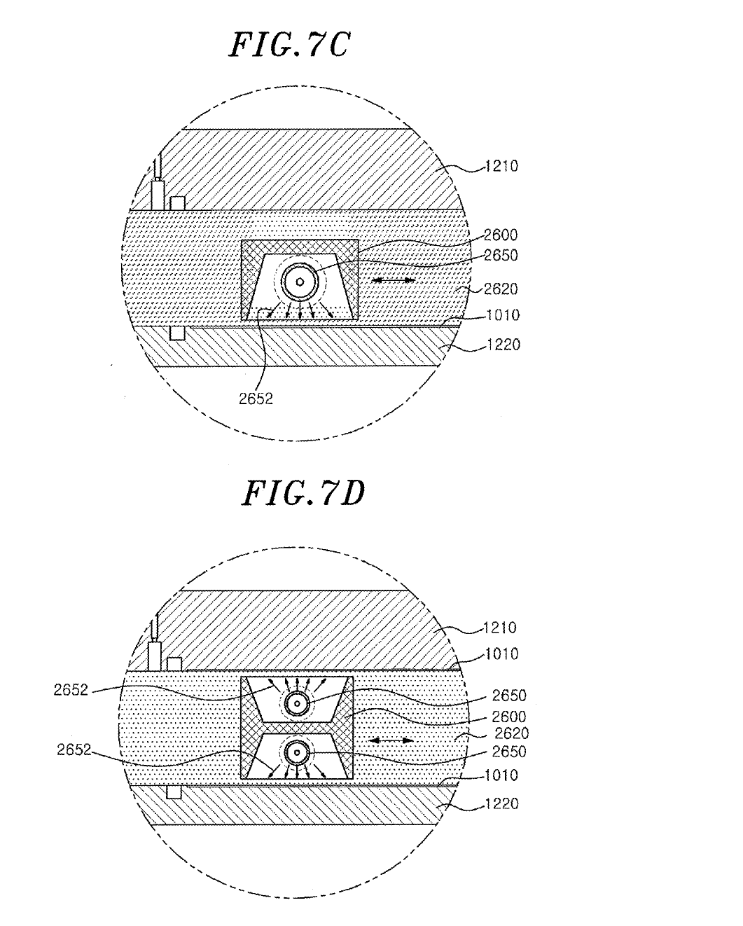

FIG. 7A is a schematic configuration view of a cross-sectional structure of a scan-type reactor and a process chamber according to an embodiment of the present invention, in which an atomic layer film forming process using plasma is performed in the scan-type reactor.

Referring to FIG. 7A, there is illustrated a structure in which a plasma-generating electrode 2610 is disposed in the lower portion of the scan-type reactor 2600.

Hereinafter, the operation will be described.

After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210. Then, the lower process chamber part 1220 is located in a predetermined position lower than the scan-type reactor 2600 positioned on one side of the process chamber 1200.

As described above, the inert reactant precursor 2620 is filled in the vacuum chamber 1100 while the lower process chamber part 1220 is coupled to the upper process chamber part 1210 and the raw material precursor adsorption step is performed. The inert reactant precursor 2620 filled in the vacuum chamber 1100 is also filled into the space between the upper process chamber part 1210 and the lower process chamber part 1220 separated from each other.

As the lower process chamber part 1220 is moved down to the predetermined position where the scan-type reactor 2600 can move in a direction parallel to the substrate 1010 of the lower process chamber part 1220, the scan-type reactor 2600 waiting at the predetermined position is made movable. Then, the scan-type reactor 2600 generates plasma 2615 on the substrate 1010 while moving over the substrate 1010 of the lower process chamber part 1220.

That is to say, at the time point at which the scan-type reactor 2600 begins to move over the substrate 1010, electric power is supplied to the plasma generating electrode 2610 formed in the lower portion of the scan-type reactor 2600, thereby generating plasma 1615 above the substrate 1010. Thus, only the inert reactant precursor 2620 existing on the substrate 1010 is selectively activated by the plasma 2615. The inert reactant precursor 2620 thus activated chemically reacts with the raw material precursor adsorbed onto the substrate 1010 to form an atomic layer film.

In the structure of the scan-type reactor 2600 illustrated in FIG. 7A, there has been described an example where the substrate 1010 is mounted on only the lower process chamber part 1220 and the atomic layer film is formed on only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 2600.

In this case, as illustrated in FIG. 7B, plasma generating electrodes 2610 for generating plasma 2615 to activate the reactant precursor may be similarly formed in the upper portion and the lower portion of the scan-type reactor 2600 so that atomic layer films can be simultaneously formed on the substrate 1010 of the upper process chamber part 1210 and the substrate 1010 of the lower process chamber part 1220.

FIG. 7C is a schematic configuration view of a cross-sectional structure of the scan-type reactor and the process chamber according to the embodiment of the present invention, in which an atomic layer film forming process using ultraviolet rays or infrared rays is performed in the scan-type reactor.

Referring to FIG. 7C, there is illustrated a structure in which an ultraviolet/infrared irradiation device 2650 for irradiating ultraviolet rays or infrared rays on the substrate 1010 is disposed in the lower portion of the scan-type reactor 2600. The ultraviolet/infrared irradiation device 2650 may be, for example, an ultraviolet lamp or an infrared lamp.

Hereinafter, the operation will be described. After the raw material precursor adsorption step and the purge step are completed in a state in which the upper process chamber part 1210 and the lower process chamber part 1220 are coupled to each other, the lower process chamber part 1220 is moved down by the moving unit 1110 to be separated from the upper process chamber part 1210. Then, the lower process chamber part 1220 is located in a predetermined position lower than the scan-type reactor 2600 positioned on one side of the process chamber 1200.

As described above, the inert reactant precursor 2620 is filled in the vacuum chamber 1100 while the lower process chamber part 1220 is coupled to the upper process chamber part 1210 and the raw material precursor adsorption step is performed. Then, the inert reactant precursor 2620 filled in the vacuum chamber 1100 is also filled into the space between the upper process chamber part 1210 and the lower process chamber part 1220 separated from each other.

As the lower process chamber part 1220 is moved down to the predetermined position where the scan-type reactor 2600 can move in a direction parallel to the substrate 1010 of the lower process chamber part 1220, the scan-type reactor 2600 waiting at the predetermined position is made movable. Then, the scan-type reactor 2600 irradiates ultraviolet rays or infrared rays 2652 on the substrate 1010 while moving over the substrate 1010 of the lower process chamber part 1220.

That is to say, at the time point at which the scan-type reactor 2600 begins to move over the substrate 1010, ultraviolet rays or infrared rays 2652 are irradiated on the substrate 1010 by the ultraviolet/infrared irradiation device 2650 provided in the lower portion of the scan-type reactor 2600. Thus, only the inert reactant precursor 2620 existing on the substrate 1010 is selectively activated by the ultraviolet rays or infrared rays 2652. The inert reactant precursor 2620 thus activated chemically reacts with the raw material precursor adsorbed onto the substrate 1010 to form an atomic layer film.

In the structure of the scan-type reactor 2600 illustrated in FIG. 7C, there has been described an example where the substrate 1010 is mounted on only the lower process chamber part 1220 and the atomic layer film is formed on only the substrate 1010 of the lower process chamber part 1220. However, in the case of employing a structure capable of mounting the substrate 1010 even to the upper process chamber part 1210, it is possible to simultaneously form atomic layer films on two substrates 1010 using the scan-type reactor 2600.

In this case, as illustrated in FIG. 7D, ultraviolet/infrared irradiation devices 2650 for irradiating ultraviolet rays or infrared rays 2652 to activate the reactant precursor may be similarly formed in the upper portion and the lower portion of the scan-type reactor 2600 so that atomic layer films can be simultaneously formed on the substrate 1010 of the upper process chamber part 1210 and the substrate 1010 of the lower process chamber part 1220.

As described above, according to the present invention, for the purpose of atomic layer deposition, a plurality of unit process chambers for atomic layer deposition process each provided with an upper process chamber part and a lower process chamber part which can be separated from and coupled to each other is disposed in a stacked form, and a scan-type reactor for causing a reactant precursor to react with a raw material precursor while moving over a substrate, onto which the raw material precursor is adsorbed, is provided in each of the unit process chambers. This makes it possible to fundamentally eliminate an area of coexistence of the raw material precursor and the reaction precursor, thereby making unnecessary any additional process for removing films which may otherwise be deposited outside the substrate, prolonging a maintenance period, suppressing generation of particles and eventually improving the quality and productivity of films. In addition, additional functions such as a heat treatment, a plasma treatment or the like can be selectively added to the scan-type reactor, thereby enabling formation of atomic layer films with various characteristics. This makes it possible to cope with different processes and to provide films optimized for needs. This also makes it possible to reduce additional facilities, thereby saving incidental expenses and maintenance costs.

While exemplary embodiments of the present invention have been described above, many different modifications may be made without departing from the spirit and scope of the present invention. For example, while the operation of the atomic layer deposition device has been described in the embodiments of the present invention, the present invention may be equally applicable to PECVD.

Accordingly, the scope of the present invention shall not be defined by the embodiments described above but shall be determined by the claims.

What is claimed is:

1. An atomic layer deposition device provided with a scan-type reactor, comprising:
a process chamber including an upper process chamber part and a lower process chamber part which are separated from or coupled to each other;
a scan-type reactor configured to wait in a predetermined position outside the process chamber and configured to, when the upper process chamber part and the lower process chamber part are separated from each other, eject a reactant precursor toward a substrate mounted on the upper process chamber part or the lower process chamber part while horizontally moving at a predetermined height above the substrate of the lower process chamber part; and
a vacuum chamber configured to support the process chamber and configured to maintain a space, in which the process chamber is positioned, in a vacuum state.

2. An atomic layer deposition device provided with a scan-type reactor, comprising:
two or more process chambers each including an upper process chamber part and a lower process chamber part which are separated from or coupled to each other;
scan-type reactors each configured to wait in a predetermined position outside each of the process chambers and configured to, when the upper process chamber part and the lower process chamber part are separated from each other, eject a reactant precursor toward a substrate mounted on the upper process chamber part or the lower process chamber part while horizontally moving at a predetermined height above the substrate of the lower process chamber part; and
a vacuum chamber configured to support the process chambers in a vertically-stacked form and configured to maintain a space, in which the process chambers are stacked, in a vacuum state.

3. The atomic layer deposition device of claim 2, wherein each of the scan-type reactors includes a gas supply portion formed in a central portion or a side portion of an upper surface or a lower surface of each of the scan-type reactors and configured to eject the reactant precursor, and a gas exhaust portion spaced apart from the gas supply portion and configured to exhaust the ejected reactant precursor failing to react with a raw material precursor existing on the substrate, a reaction byproduct or a purge gas.

4. The atomic layer deposition device of claim 3, wherein each of the scan-type reactors further includes a purge gas supply portion formed in opposite side portions or a peripheral portion of the upper surface or the lower surface of each of the scan-type reactors and configured to eject the purge gas.

5. The atomic layer deposition device of claim 4, wherein each of the scan-type reactors is configured to, when the reactant precursor is ejected toward the substrate, cause the purge gas supply portion to eject the purge gas to form a gas barrier between each of the scan-type reactors and the substrate.

6. The atomic layer deposition device of claim 4, wherein the purge gas supply portion is formed in each of the scan-type reactors at an outer side of the gas supply portion and the gas exhaust portion.

7. The atomic layer deposition device of claim 3, wherein each of the scan-type reactors further includes an electrode provided in an upper portion or a lower portion of each of the scan-type reactors and configured to generate plasma.

8. The atomic layer deposition device of claim 7, wherein each of the scan-type reactors is configured to, when the reactant precursor is ejected toward the substrate, supply electric power to the electrode to generate plasma above or below each of the scan-type reactors.

9. The atomic layer deposition device of claim 2, wherein the scan-type reactors are provided in the process chambers in a one-to-one relationship and are driven independently or simultaneously through a connection member which interconnects the scan-type reactors.

10. The atomic layer deposition device of claim 9, wherein the scan-type reactors are moved by a reactor moving unit which moves the connection member.

11. The atomic layer deposition device of claim 10, wherein the reactor moving unit is supported by the vacuum chamber.

12. The atomic layer deposition device of claim 2, wherein the scan-type reactors are supported by the vacuum chamber.

13. The atomic layer deposition device of claim 2, wherein each of the scan-type reactors includes a heat treatment unit or an ultraviolet treatment unit configured to perform cleaning or surface modification with respect to the substrate or a film formed on the substrate.

14. An atomic layer deposition device provided with a scan-type reactor, comprising:
a process chamber including an upper process chamber part and a lower process chamber part which are separated from or coupled to each other;
a scan-type reactor configured to wait in a predetermined position outside the process chamber and configured to, when the upper process chamber part and the lower process chamber part are separated from each other, cause an inert reactant precursor introduced into the process chamber to react with a raw material precursor on a substrate while horizontally moving at a predetermined height above the substrate of the lower process chamber part; and
a vacuum chamber configured to support the process chamber, configured to maintain a space, in which the process chamber is positioned, in a vacuum state, and configured to supply and exhaust the inert reactant precursor.

15. An atomic layer deposition device provided with a scan-type reactor, comprising:
two or more process chambers each including an upper process chamber part and a lower process chamber part which are separated from or coupled to each other;
scan-type reactors each configured to wait in a predetermined position outside each of the process chambers and configured to, when the upper process chamber part and the lower process chamber part are separated from each other, cause an inert reactant precursor introduced into each of the process chambers to react with a raw material precursor on a substrate while horizontally moving at a predetermined height above the substrate of the lower process chamber part; and
a vacuum chamber configured to support the process chambers in a vertically-stacked form, configured to maintain a space, in which the process chambers are stacked, in a vacuum state, and configured to supply and exhaust the inert reactant precursor.

16. The atomic layer deposition device of claim 15, wherein each of the scan-type reactors is configured to selectively activate only the inert reactant precursor existing on the substrate by generating plasma on the substrate mounted on the upper process chamber part or the lower process chamber part and is configured to cause the activated inert reactant precursor to react with the raw material precursor.

17. The atomic layer deposition device of claim 15, wherein each of the scan-type reactors is configured to selectively activate only the inert reactant precursor existing on the substrate by irradiating ultraviolet rays or infrared rays toward the substrate mounted on the upper process chamber part or the lower process chamber part and is configured to cause the activated inert reactant precursor to react with the raw material precursor.

18. The atomic layer deposition device of claim 16, wherein each of the scan-type reactors further includes an electrode provided in an upper portion or a lower portion of each of the scan-type reactors and configured to generate plasma.

19. The atomic layer deposition device of claim 18, wherein each of the scan-type reactors is configured to, when each of the scan-type reactors moves toward the substrate, supply electric power to the electrode to generate plasma above or below each of the scan-type reactors.

20. The atomic layer deposition device of claim 17, wherein each of the scan-type reactors includes an ultraviolet irradiation device or an infrared irradiation device installed in an upper portion or a lower portion of each of the scan-type reactors and configured to irradiate the ultraviolet rays or the infrared rays.

21. The atomic layer deposition device of claim 20, wherein each of the scan-type reactors is configured to, when each of the scan-type reactors moves toward the substrate, drive the ultraviolet irradiation device or the infrared irradiation device to irradiate the ultraviolet rays or the infrared rays above or below each of the scan-type reactors.

22. The atomic layer deposition device of claim 15, wherein the inert reactant precursor is a substance which reacts with the raw material precursor when activated by plasma, ultraviolet rays or infrared rays.

23. The atomic layer deposition device of claim 15, wherein the inert reactant precursor is filled into the vacuum chamber under a predetermined pressure.

24. The atomic layer deposition device of claim 15, wherein when the upper process chamber part and the lower process chamber part are separated from each other after the raw material precursor is adsorbed to the substrate, the inert reactant precursor is diffused and introduced from the vacuum chamber into a space between the upper process chamber part and the lower process chamber part separated from each other.

25. The atomic layer deposition device of claim 15, wherein when the upper process chamber part and the lower process chamber part are coupled to each other after the substrate is loaded into each of the process chambers, the inert reactant precursor is filled into the vacuum chamber.

26. An atomic layer deposition method performed in an atomic layer deposition device in which a process chamber is positioned within a vacuum chamber, the method comprising:
coupling an upper process chamber part and a lower process chamber part of the process chamber to form a sealed reaction space, after a substrate and a mask are loaded into the process chamber;
causing a raw material precursor to be adsorbed onto the substrate by performing an atomic layer deposition process within the sealed reaction space;
ejecting a reactant precursor toward the substrate using a scan-type reactor, after the raw material precursor is adsorbed onto the substrate; and
causing the reactant precursor ejected toward the substrate to react with the raw material precursor.

27. An atomic layer deposition method performed in a stacking-type atomic layer deposition device in which two or more process chambers are stacked within a vacuum chamber, the method comprising:
coupling an upper process chamber part and a lower process chamber part of each of the process chambers to form a sealed reaction space, after a substrate and a mask are loaded into each of the process chambers;
causing a raw material precursor to be adsorbed onto the substrate by performing an atomic layer deposition process within the sealed reaction space;
ejecting a reactant precursor toward the substrate using a scan-type reactor, after the raw material precursor is adsorbed onto the substrate; and
causing the reactant precursor ejected toward the substrate to react with the raw material precursor.

28. The atomic layer deposition method of claim 27, wherein the ejecting the reactant precursor includes:
separating the upper process chamber part and the lower process chamber part from each other after the raw material precursor is adsorbed onto the substrate; and
ejecting the reactant precursor toward the substrate while moving the scan-type reactor in a space between the upper process chamber part and the lower process chamber part.

29. The atomic layer deposition method of claim 28, wherein in the ejecting the reactant precursor, the reactant precursor is ejected toward the substrate mounted on the upper process chamber part or the lower process chamber part, while horizontally moving the scan-type reactor at a predetermined height above the substrate of the lower process chamber part.

30. The atomic layer deposition method of claim 28, wherein in the ejecting the reactant precursor, when the reactant precursor is ejected toward the substrate through the scan-type reactor, a purge gas is ejected from opposite side portions or a peripheral portion of an upper surface or a lower surface of the scan-type reactor to form a gas barrier between the scan-type reactor and the substrate.

31. The atomic layer deposition method of claim 28, wherein in the ejecting the reactant precursor, when the reactant precursor is ejected toward the substrate through the scan-type reactor, plasma is generated above or below the scan-type reactor.

32. The atomic layer deposition method of claim 28, wherein in the ejecting the reactant precursor, when the reactant precursor is ejected toward the substrate through the scan-type reactor, an unreacted reactant precursor, a reaction byproduct or a purge gas existing between the scan-type reactor and the substrate is exhausted through a gas exhaust portion formed in opposite side portions or a peripheral portion of an upper surface or a lower surface of the scan-type reactor.

33. The atomic layer deposition method of claim 27, wherein the scan-type reactor is supported by the vacuum chamber and is configured to wait in a predetermined position outside each of the process chambers.

34. The atomic layer deposition method of claim 27, wherein the scan-type reactor includes one or more scan-type reactors provided in each of the process chambers and driven independently or simultaneously through a connection member which interconnects the scan-type reactors.

35. An atomic layer deposition method performed in an atomic layer deposition device in which a process chamber is positioned within a vacuum chamber, the method comprising:
coupling an upper process chamber part and a lower process chamber part of the process chamber to form a sealed reaction space, after a substrate and a mask are loaded into the process chamber;
causing a raw material precursor to be adsorbed onto the substrate by performing an atomic layer deposition process within the sealed reaction space; and
causing an inert reactant precursor introduced into the process chamber to react with the raw material precursor on the substrate using a scan-type reactor, after the raw material precursor is adsorbed onto the substrate.

36. An atomic layer deposition method performed in a stacking-type atomic layer deposition device in which two or more process chambers are stacked within a vacuum chamber, the method comprising:
coupling an upper process chamber part and a lower process chamber part of each of the process chambers to form a sealed reaction space, after a substrate and a mask are loaded into each of the process chambers;
causing a raw material precursor to be adsorbed onto the substrate by performing an atomic layer deposition process within the sealed reaction space; and
causing an inert reactant precursor introduced into each of the process chambers to react with the raw material precursor on the substrate using a scan-type reactor, after the raw material precursor is adsorbed onto the substrate.

37. The atomic layer deposition method of claim 36, wherein the causing the inert reactant precursor to react with the raw material precursor includes:
separating the upper process chamber part and the lower process chamber part after the raw material precursor is adsorbed onto the substrate,
moving the scan-type reactor over the substrate of the upper process chamber part or the lower process chamber part; and
causing the inert reactant precursor to react with the raw material precursor on the substrate by activating the inert reactant precursor using plasma, ultraviolet rays or infrared rays generated from the scan-type reactor.

38. The atomic layer deposition method of claim 37, wherein in the causing the inert reactant precursor to react with the raw material precursor, only the inert reactant precursor introduced into each of the process chambers and existing on the substrate is selectively activated using the plasma, the ultraviolet rays or the infrared rays and is caused to react with the raw material precursor.

39. The atomic layer deposition method of claim 37, wherein in the causing the inert reactant precursor to react with the raw material precursor, when the scan-type reactor is moved toward the substrate, the plasma is generated above the substrate through the scan-type reactor to activate the inert reactant precursor.

40. The atomic layer deposition method of claim 37, wherein in the causing the inert reactant precursor to react with the raw material precursor, when the scan-type reactor is moved toward the substrate, the ultraviolet rays or the infrared rays are irradiated toward the substrate through the scan-type reactor to activate the inert reactant precursor.

41. The atomic layer deposition method of claim 36, wherein the inert reactant precursor is a substance which reacts with the raw material precursor when activated by plasma, ultraviolet rays or infrared rays.

42. The atomic layer deposition method of claim 36, wherein when the upper process chamber part and the lower process chamber part are separated from each other after the raw material precursor is adsorbed to the substrate, the inert reactant precursor is diffused and introduced from the vacuum chamber into a space between the upper process chamber part and the lower process chamber part separated from each other.

43. The atomic layer deposition method of claim 36, wherein when the upper process chamber part and the lower process chamber part are coupled to each other after the substrate is loaded into each of the process chambers, the inert reactant precursor is filled into the vacuum chamber.

44. The atomic layer deposition method of claim 36, wherein the scan-type reactor is supported by the vacuum chamber and is configured to wait in a predetermined position outside each of the process chambers.
